(19) United States
(12) Patent Application Publication
(10) Pub. No.: US 2025/0227893 A1
(43) Pub. Date: Jul. 10, 2025

(54) FAN CONTROL SYSTEM, SERVER SYSTEM, AND FAN CONTROL METHOD AND APPARATUS

(71) Applicant: Suzhou MetaBrain Intelligent Technology Co., Ltd., Suzhou (CN)

(72) Inventors: Siheng LUO, Suzhou (CN); Cai KONG, Suzhou (CN); Menghua CAO, Suzhou (CN)

(21) Appl. No.: 19/091,254

(22) Filed: Mar. 26, 2025

Related U.S. Application Data
(63) Continuation of application No. PCT/CN2024/097349, filed on Jun. 4, 2024.

(30) Foreign Application Priority Data
Jul. 26, 2023 (CN) 202310922112.1

(51) Int. Cl. H05K 7/20; F04D 27/00

(52) U.S. Cl. CPC H05K 7/20836; F04D 27/008

(57) ABSTRACT

A fan control system, a server system, and a fan control method and apparatus. The fan control system includes a measurement circuit and a delay circuit, the measurement circuit acquiring a first voltage of an alternating current power supply and/or a second voltage output by a power supply unit during rotating of a fan; when the first voltage and/or the second voltage drops, a mainboard stops outputting a closing signal to the delay circuit, whereby an energy storage unit discharges within a preset time, the delay circuit being provided between an output end of the mainboard and an enabling end of an overcurrent protection switch, and the delay time of the delay circuit being the preset time. The mainboard is used for outputting, when the server system satisfies a preset cooling condition, the closing signal to the overcurrent protection switch by means of the delay circuit.

### CROSS-REFERENCE TO RELATED APPLICATION

This application is a continuation of and claims priority to International Patent Application No. PCT/CN2024/097349, filed on Jun. 4, 2024, which claims priority to Chinese Patent Application No. 202310922112.1, filed on Jul. 26, 2023 in China National Intellectual Property Administration and entitled “FAN CONTROL SYSTEM, SERVER SYSTEM, AND FAN CONTROL METHOD AND APPARATUS”. International Patent Application No. PCT/CN2024/097349 and Chinese Patent Application No. 202310922112.1 are incorporated herein in their entireties by reference.

### FIELD

The present application relates to the field of server security protection, and more particularly, to a fan control system, a server system, a fan control method, and a fan control apparatus.

### BACKGROUND

In the server system, an alternating current is input to a Power Supply Unit (PSU), which converts the alternating current into a direct current to supply power to the mainboard and fans within the server system. When the alternating current voltage drops, the direct current voltage output by the PSU also drops, causing insufficient power supply to the fan and a reduction in a rotating speed of the fan. When the rotating speed of the fan decreases rapidly, the fan controller performs closed-loop control on the rotating speed of the fan, thereby increasing a duty cycle of a Pulse Width Modulation (PWM) signal, induces a large surge current, and may trigger the overcurrent protection switch of the fan, causing the fan to stall. The inventors have recognized that when the alternating current power and the PSU are recovered to normal operation, components such as the mainboard in the server system will continue to operate. However, there is a risk of damage due to overheating of critical components caused by stalling of the fan.

### SUMMARY

The present application provides a fan control system, a server system, a fan control method and apparatus. By utilizing a delay circuit, the triggering of an overcurrent protection switch of a fan can be prevented, thereby avoiding the fan's stalling caused by the disconnection of the overcurrent protection switch, which ensures that the fan can resume operation after the first voltage and the second voltage return to normal, thereby maintaining the heat dissipation efficiency of critical components in the server system and preventing the risk of damage due to excessive temperature.

In a first aspect, the present application provides a fan control system applied to a server system, the server system includes a power supply unit, a mainboard, an overcurrent protection switch, an energy storage unit, a fan controller, and a fan; an input end of the power supply unit is configured to receive an alternating current power supply, an output end of the power supply unit is connected to a power terminal of the mainboard and is connected to the energy storage unit, a power terminal of the fan controller, and a power terminal of the fan via the overcurrent protection switch, an output end of the mainboard is connected to an enabling end of the overcurrent protection switch, and the fan controller is connected to the fan;

the fan control system includes:

a measurement circuit having an input end connected to the input end and/or the output end of the power supply unit and an output end connected to the mainboard, and configured to acquire a first voltage of the alternating current power supply and/or a second voltage output by the power supply unit during rotating of the fan;

a delay circuit provided between the output end of the mainboard and the enabling end of the overcurrent protection switch, where the delay time of the delay circuit is a preset time; where

the mainboard is configured to output a closing signal to the overcurrent protection switch through the delay circuit when the server system meets a preset cooling condition, where the overcurrent protection switch is closed after the preset time, and to stop outputting the closing signal to the delay circuit when the first voltage drops to a first preset voltage and/or the second voltage drops to a second preset voltage, whereby the energy storage unit discharges within the preset time, thereby the fan controller is power off.

In some embodiments, the measurement circuit is configured to acquire the second voltage output by the power supply unit during the rotating of the fan; and the fan control system further includes:

an undervoltage measurement circuit having an input end connected to the output end of the power supply unit and the power terminal of the fan controller and an output end connected to a reset end of the fan controller, configured to compare the second voltage output by the power supply unit with a threshold voltage of the fan controller, and to output a reset signal to the reset end of the fan controller when the second voltage is less than the threshold voltage, thereby resetting the fan controller to trigger the fan controller to re-regulate a rotating speed of the fan.

In some embodiments, the undervoltage measurement circuit includes:

a sampling circuit having an input end connected to the power terminal of the fan controller for acquiring the threshold voltage of the fan controller; and

a comparison circuit having a first input end connected to the output end of the measurement circuit, a second input end connected to an output end of the sampling circuit, and an output end connected to the reset end of the fan controller, configured to output the reset signal to the reset end of the fan controller when the second voltage output by the power supply unit is less than the threshold voltage of the fan controller, thereby resetting the fan controller to trigger the fan controller to re-regulate the rotating speed of the fan.

In some embodiments, the comparison circuit is a comparator; a positive input end is connected to the output end of the measurement circuit, a negative input end is connected to the output end of the sampling circuit, and an output end is connected to the reset end of the fan controller, configured to output a low-level signal to the reset end of the fan controller when the second voltage output by the power supply unit is less than the threshold voltage of the fan controller, thereby resetting the fan controller to trigger the fan controller to re-regulate the rotating speed of the fan;

or, the negative input end is connected to the output end of the measurement circuit, the positive input end is connected to the output end of the sampling circuit, and the output end is connected to the reset end of the fan controller, configured to output a high-level signal to the reset end of the fan controller when the second voltage output by the power supply unit is less than the threshold voltage of the fan controller, thereby resetting the fan controller to trigger the fan controller to re-regulate the rotating speed of the fan.

In some embodiments, the sampling circuit includes a first resistor and a second resistor; the first resistor has one end connected to the power terminal of the fan controller and has the other end connected to one end of the second resistor and served as the output end of the sampling circuit, and the other end of the second resistor is grounded.

In some embodiments, when the measurement circuit is configured to detect a second voltage of the power supply unit, the measurement circuit includes a third resistor and a fourth resistor; the third resistor has one end connected to the output end of the power supply unit and has the other end connected to one end of the fourth resistor and served as the output end of the measurement circuit, and the other end of the fourth resistor is grounded.

In some embodiments, the delay time of the delay circuit is determined according to a type of the fan controller and a type of the fan; and the preset time is not less than a preset multiple of the discharge time, where the discharge time is the time required for a power supply voltage of the fan controller to drop to a threshold voltage during the discharge process of the energy storage unit.

In some embodiments, the energy storage unit is a capacitor.

In some embodiments, the delay circuit is a time or a time counter or an Resistor-Capacitor (RC) circuit.

In some embodiments, the system further includes a filtering apparatus provided between the output end of the measurement circuit and the mainboard for filtering a first voltage and/or a second voltage acquired by the measurement circuit.

In some embodiments, a prompt apparatus connected to the mainboard for outputting prompt information when it is determined that the first voltage drops to a first preset voltage and/or when it is determined that the second voltage drops to a second preset voltage.

In some embodiments, the prompt apparatus is a voice prompt apparatus and/or a display prompt apparatus and/or a vibrating prompt apparatus.

In some embodiments, the mainboard is configured to stop outputting the closing signal to the delay circuit when the first voltage drops to a first preset voltage and/or the second voltage drops to a second preset voltage, whereby the delay circuit delays for the preset time and then stops outputting the closing signal to the overcurrent protection switch, whereby the energy storage discharges for the preset time, thereby causing the fan controller to be powered down.

In a second aspect, the present application provides a server system including a power supply unit, a mainboard, an overcurrent protection switch, an energy storage unit, a fan controller, a fan, and the fan control system as described above.

An input end of the power supply unit is configured to receive an alternating current power supply, an output end of the power supply unit is connected to a power terminal of the mainboard and is connected to the energy storage unit, a power terminal of the fan controller, and a power terminal of the fan via the overcurrent protection switch, an output end of the mainboard is connected to an enabling end of the overcurrent protection switch, and the fan controller is connected to the fan; an input end of the fan control system is connected to the input end and/or the output end of the power supply unit, and an output end of the fan control system is connected to the fan controller.

In a third aspect, the present application further provides a fan control method applied to the above described fan control system, the method including:

during rotating of the fan, acquiring a first voltage of an alternating current power supply and/or a second voltage output by a power supply unit; and

when the first voltage drops to a first preset voltage and/or the second voltage drops to a second preset voltage, controlling the mainboard to continuously output the closing signal to an overcurrent protection switch for a preset time, whereby the energy storage unit discharges for the preset time, thereby controlling the fan controller to be powered down.

In some embodiments, the method further includes:

when a preset cooling condition is met, controlling the mainboard to output the closing signal to the overcurrent protection switch, whereby the overcurrent protection switch is closed after a preset time delay, thereby starting the fan.

In some embodiments, the server system further includes an electronic device to be cooled connected to the mainboard, and the method further includes:

determining whether the electronic device to be cooled is connected to the mainboard;

if so, it is determined that the preset cooling condition is met.

In some embodiments, the when the first voltage drops to the first preset voltage and/or the second voltage drops to the second preset voltage, controlling the mainboard to continuously output the closing signal for the preset time to the overcurrent protection switch, whereby the energy storage unit discharges for the preset time, thereby controlling the fan controller to be powered down includes:

when the first voltage drops to a first preset voltage and/or the second voltage drops to a second preset voltage, controlling the mainboard to continuously output the closing signal to an overcurrent protection switch for a preset time, whereby the energy storage unit discharges for the preset time, thereby controlling the fan controller to be powered down.

In some embodiments, the method further includes:

when the first voltage drops to a first preset voltage and/or the second voltage drops to a second preset voltage, resetting the fan controller to trigger the fan controller to re-regulate a rotating speed of the fan;

In some embodiments, before resetting the fan controller to trigger the fan controller to re-regulate the rotating speed of the fan, the method further includes:

determining whether the second voltage output by the power supply unit is less than the threshold voltage of the fan controller;

if less, determining that the first voltage drops to the first preset voltage and/or the second voltage drops to the second preset voltage, and proceeding a step of resetting the fan controller to trigger the fan controller to re-regulate the rotating speed of the fan.

In some embodiments, an undervoltage measurement circuit in the fan control system includes a sampling circuit and a comparison circuit for detecting a threshold voltage of the fan controller, the measurement circuit being connected to a first input end of the comparison circuit, and the sampling circuit being connected to a second input end of the comparison circuit;

the determining whether the second voltage output by the power supply unit is less than the threshold voltage of the fan controller includes:

comparing, via the comparison circuit, whether a voltage value at a first input end is less than a voltage value at a second input end of the comparison circuit;

if the voltage value at the first input end is lower than the voltage value at the second input end, determining that the second voltage output by the power supply unit is less than the threshold voltage of the fan controller; otherwise, determining that the second voltage output by the power supply unit is not below the threshold voltage of the fan controller.

In some embodiments, the when the first voltage drops to a first preset voltage and/or the second voltage drops to a second preset voltage, resetting the fan controller to trigger the fan controller to re-regulate a rotating speed of the fan includes:

when it is determined that the voltage value at the first input end is less than the voltage value at the second input end, triggering the comparison circuit to output a reset signal to the fan controller to reset the fan controller, thereby triggering the fan controller to re-regulate the rotating speed of the fan.

In some embodiments, after acquiring a first voltage of an alternating current power supply and/or a second voltage output by a power supply unit, the method further includes:

determining whether a first difference between a first reference voltage and the first voltage is greater than a first threshold, and/or determining whether a second difference between a second reference voltage and the second voltage is greater than a second threshold;

if the first difference is greater than the first threshold, determining that the first voltage drops to the first preset voltage;

if the second difference is greater than the second threshold, determining that the second voltage drops to the second preset voltage.

In some embodiments, after acquiring a first voltage of an alternating current power supply and/or a second voltage output by a power supply unit, the method further includes:

filtering the first voltage and/or the second voltage.

In some embodiments, the when the first voltage drops to the first preset voltage and/or the second voltage drops to the second preset voltage, controlling the mainboard to continuously output the closing signal for the preset time to the overcurrent protection switch, whereby the energy storage unit discharges for the preset time, thereby controlling the fan controller to be power down includes:

determining whether a duration for the first voltage dropping to the first preset voltage and/or the second voltage dropping to the second preset voltage reaches a time threshold;

if so, controlling the mainboard to continuously output the closing signal to an overcurrent protection switch for a preset time, whereby the energy storage unit discharges for the preset time, thereby controlling the fan controller to be powered down.

In some embodiments, after when the first voltage drops to the first preset voltage and/or the second voltage drops to the second preset voltage, controlling the mainboard to continuously output the closing signal for the preset time to the overcurrent protection switch, whereby the energy storage unit discharges for the preset time, thereby controlling the fan controller to be powered down, the method further includes:

when the first voltage is recovered and the second voltage is recovered, controlling the fan controller to be re-power on to restart the fan.

In some embodiments, the when the first voltage is recovered and the second voltage is recovered, controlling the fan controller to be re-power on to restart the fan includes:

when the first voltage is recovered and the second voltage is recovered, delaying to control the fan controller to be re-power on to restart the fan.

In a fourth aspect, the present application further provides a fan control apparatus applied to the above described fan control system and including:

a voltage acquisition unit configured to, during rotating of the fan, acquiring a first voltage of an alternating current power supply and/or a second voltage output by a power supply unit; and

a controller configured to, when the first voltage drops to a first preset voltage and/or the second voltage drops to a second preset voltage, control the mainboard to continuously output the closing signal to an overcurrent protection switch for a preset time, whereby the energy storage unit discharges for the preset time, thereby controlling the fan controller to be powered down.

### BRIEF DESCRIPTION OF THE DRAWINGS

To describe the technical solutions of the embodiments of the present application more clearly, the following briefly introduces the accompanying drawings required for describing the prior art and the embodiments. Apparently, the accompanying drawings in the following description show only some embodiments of the present application, and a person of ordinary skill in the art may still derive other drawings from these accompanying drawings without creative efforts.

FIG. 1 is a structural block diagram illustrating a server system;

FIG. 2 is a schematic waveform diagram illustrating a voltage drop according to one or more embodiments of the present application;

FIG. 3 is a schematic diagram illustrating a universal power supply structure for a fan according to one or more embodiments of the present application;

FIG. 4 is a schematic diagram illustrating an internal power supply of a fan according to one or more embodiments of the present application;

FIG. 5 is a structural block diagram illustrating a fan control system according to one or more embodiments of the present application;

FIG. 6 is a schematic diagram illustrating an improved power supply structure of a fan according to one or more embodiments of the present application;

FIG. 7 is a schematic diagram illustrating an improved internal power supply of a fan according to one or more embodiments of the present application;

FIG. 8 is a structural block diagram illustrating a server system according to one or more embodiments of the present application;

FIG. 9 is a schematic flow diagram illustrating a fan control method according to one or more embodiments of the present application;

FIG. 10 is a structural block diagram illustrating a fan control apparatus according to one or more embodiments of the present application; and

FIG. 11 is a structural block diagram illustrating a fan control apparatus according to one or more embodiments of the present application.

### DETAILED DESCRIPTION

The core of the present application is to provide a fan control system, a server system, a fan control method and apparatus. By utilizing a delay circuit, the triggering of an overcurrent protection switch of a fan can be prevented, thereby avoiding the fan's stalling caused by the disconnection of the overcurrent protection switch, which ensures that the fan can resume operation after the first voltage and the second voltage return to normal, thereby maintaining the heat dissipation efficiency of critical components in the server system and preventing the risk of damage due to excessive temperature.

In order that the objects, aspects, and advantages of the embodiments of the present application will become more apparent, a more complete description of the embodiments of the present application will be rendered by reference to the appended drawings, which are provided for purposes of illustration and are not intended to be exhaustive or limiting of the present application. Based on the embodiments in the present application, all other embodiments obtained by a person skilled in the art without involving any inventive effort are within the protection scope of the present application.

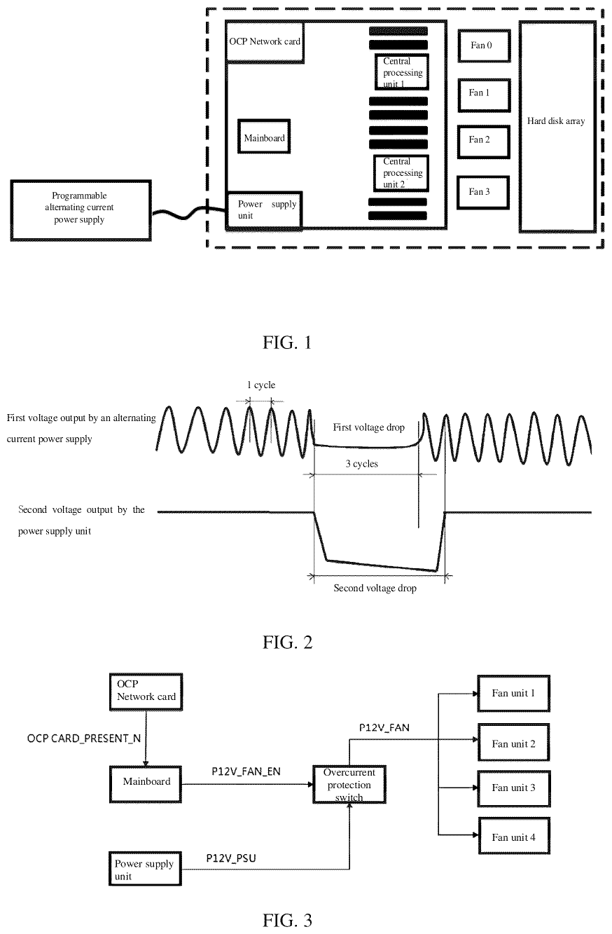

Referring specifically to FIG. 1, FIG. 1 is a structural block diagram illustrating a server system. A programmable alternating current power supply is input to a power supply unit, which then supplies power to a server system, such as a mainboard, an Open Compute Project (OCP) network card, a central processing unit, a fan, and a hard disk array. Referring to FIG. 2, FIG. 2 is a waveform diagram illustrating a voltage drop according to the present application. In contemporary server systems, insufficient power supply to the fan may lead to a reduction in a rotating speed of the fan. The fan controller performs closed-loop control on the rotating speed of the fan, thereby increasing a duty cycle of a PWM signal, induces a large surge current, and thus triggers the overcurrent protection switch of the fan to turn on, causing the fan to stall. At this moment, despite the alternating current and power supply unit recovering normal power supply, critical components may overheat and be at risk of damage due to the fan stalling.

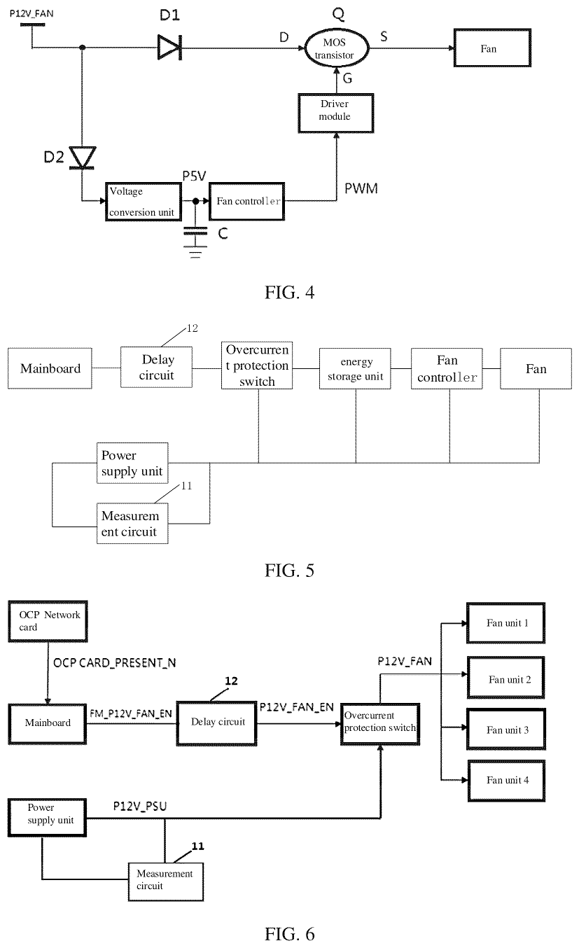

For a more comprehensive understanding of the fan power supply principle, referring to FIGS. 3 and 4, where FIG. 3 is a schematic diagram illustrating a general power supply structure for a fan according to the present application, and FIG. 4 is a schematic diagram illustrating an internal power supply of a fan according to the present application. In FIG. 3, upon power on of the power supply unit, P12V_PSU is output to supply standby power to the mainboard. At this time, the mainboard (or a certain processor on the mainboard) will detect a presence status of an OCP network card (a device to be cooled). If the presence of the OCP network card is detected (the OCP CARD_PRESENT_N signal is active low), the mainboard will issue the P12V_FAN_EN signal to close the overcurrent protection switch, thereby outputting the P12V_FAN voltage to power system fan units 1-4. In FIG. 4, P12V_PSU outputs P12V_FAN via the overcurrent protection switch. P12V_FAN served as the power supply input for the fan unit and is split into two circuits upon entering the fan unit. A first path supplies power to the fan (specifically, a fan motor) via an isolation diode D1 and an MOS transistor Q. A second path passes through the isolation diode D2, and then the voltage conversion unit outputs P5V to power the fan controller. The fan controller automatically regulates the rotating speed of the fan based on the detected rotating speed of the fan, and outputs a PWM signal which is processed by the driver module to generate a control signal for the MOS transistor Q, thereby controlling the rotating speed of the fan motor.

In a first aspect, referring to FIG. 5, FIG. 5 is a block diagram illustrating a fan control system according to the present application, referring to FIG. 6, FIG. 6 is a schematic diagram illustrating an improved power supply structure for a fan according to the present application.

The fan control system is applied to a server system, the server system includes a power supply unit, a mainboard, an overcurrent protection switch, an energy storage unit, a fan controller, and a fan; an input end of the power supply unit is configured to receive an alternating current power supply, an output end of the power supply unit is connected to a power terminal of the mainboard and is connected to the energy storage unit, a power terminal of the fan controller, and a power terminal of the fan via the overcurrent protection switch, an output end of the mainboard is connected to an enabling end of the overcurrent protection switch, and the fan controller is connected to the fan;

the fan control system includes:

a measurement circuit 11 having an input end connected to the input end and/or the output end of the power supply unit and an output end connected to the mainboard, and configured to acquire a first voltage of the alternating current power supply and/or a second voltage output by the power supply unit during rotating of the fan;

a delay circuit 12 provided between the output end of the mainboard and the enabling end of the overcurrent protection switch, where the delay time of the delay circuit is a preset time;

the mainboard is configured to output a closing signal to the overcurrent protection switch through the delay circuit 12 when the server system meets a preset cooling condition, such that the overcurrent protection switch is closed after the preset time, and to stop outputting the closing signal to the delay circuit 12 when the first voltage drops to a first preset voltage and/or the second voltage drops to a second preset voltage, whereby the energy storage unit discharges within the preset time, thereby the fan controller is power down.

In some embodiments, the current voltage state is monitored by the measurement circuit 11 acquiring a first voltage of the alternating current power supply and/or a second voltage output by the power supply unit. The first voltage may be directly acquired from an alternating current power supply, and the second voltage may be output from the power supply unit. By monitoring these voltages, the status of the alternating current and the power supply unit can be ascertained in real time, and corresponding control measures can be implemented based on this information. It enables the system to promptly detect voltage drop conditions, thereby providing precise triggering condition for subsequent fan control.

In some embodiments, the overcurrent protection switch is configured to monitor whether the current is greater than a rated range. When the current is greater than the rated range, the overcurrent protection switch will automatically disconnect the circuit to ensure safe operation of the system. The energy storage unit is configured to provide a reserve of electric energy for a preset time of time in the event of an unstable power supply or a sudden power off, thereby ensuring the normal operation of the fan and preventing the server system from shutting down due to power fluctuations or interruptions. The specific implementation of the energy storage unit may be, but is not limited to, a capacitor. From a technical principle perspective, reliable control of the fan might be achieved by utilizing an overcurrent protection switch and an energy storage unit. During normal operation of the fan, the power supply status is monitored in real time by acquiring the voltage of the alternating current power supply and the output voltage of the power supply unit. When the voltage of the alternating current power supply or the output voltage of the power supply unit drops below a preset value, the fan controller is controlled to power down, thereby preventing the adverse impact of excessively low voltage on the normal operation of the fan.

For example, when the alternating current power supply voltage utilized by the server system decreases or the output voltage of the power supply unit drops to a preset value, the fan controller is controlled to enter a power down state, thereby protecting the fan from the effects of an excessively low voltage. In addition, when the current is greater than the rated range, the overcurrent protection switch automatically disconnects the circuit, thereby ensuring the safe operation of the entire system. In addition, additional voltage regulators or power management devices may be incorporated between the fan controller and the energy storage unit to enhance the reliability and stability of fan control.

In some embodiments, the delay time is configured by a delay circuit 12 in the server system to control the timing at which the mainboard outputs a closing signal to the overcurrent protection switch. In some embodiments, the delay circuit 12 is arranged between the output end of the mainboard and the enabling end of the overcurrent protection switch. By presetting the delay time to a desired time interval, the function of continuously outputting a closing signal to the overcurrent protection switch can be achieved.

In some embodiments, when the first voltage or the second voltage drops to the corresponding preset voltage, the mainboard begins to output the closing signal to the delay circuit 12. The delay circuit 12 maintains the output of the closing signal according to a preset delay time and stops the output of the closing signal after a preset time interval. This enables time control under certain conditions through the control of the delay circuit 12. That is, after being controlled by the delay circuit 12, the closing signal reaches the enabling end of the overcurrent protection switch, thereby causing the overcurrent protection switch to be turned off. The closed overcurrent protection switch causes the energy storage unit to initiate discharge, thereby controlling reducing the supply voltage of the fan controller below the threshold voltage. As such, the fan controller will lose power supply and power down.

By incorporating the delay circuit 12, the power down timing of the fan controller can be controlled with greater precision. The delay time of the delay circuit 12 is adjustable and presettable based on specific requirements (particularly, it can be adjusted according to the time required for the supply voltage of the fan controller to drop to the threshold voltage during the discharge process of the energy storage unit), thereby enabling flexible control of the power down time of the fan controller under various conditions.

In summary, in some embodiments, by introducing the delay circuit 12 and optimizing the control method, the performance and reliability of the server system are enhanced, while also providing a more flexible and intelligent fan control strategy, thereby offering convenience and assurance for the operation and maintenance of the server system.

In summary, some embodiments provide an improved server system. By incorporating the overcurrent protection switch and the energy storage unit, the system enables reliable control of the fan, ensures the normal operation of the fan under unstable power conditions, and enhances the safety and reliability of the overall system.

In some embodiments, once the first voltage drops below the first preset voltage or the second voltage drops below the second preset voltage, the mainboard is controlled to continuously output a closing signal to the overcurrent protection switch to prevent the overcurrent protection switch from being disconnected, thereby enabling the energy storage unit to discharge for a preset time to reduce the power supply voltage of the fan controller below the threshold voltage, thereby achieving a power down operation. As such, it is possible to prevent malfunction or damage that may arise from continuing to operate the fan controller under excessively low voltage conditions.

In the implementation process, different preset voltages and threshold voltages might be configured to satisfy the requirements of various server systems. For example, based on the performance and load conditions of the server system, a lower preset voltage and threshold voltage might be configured to power down when the voltage decreases to a certain level, thereby ensuring that the fan controller is not impacted by an excessively low voltage.

It can be seen that in some embodiments, the server system might be ensured to be power down timely when the voltage decreases to a certain level, and a stable power supply might be provided by utilizing the overcurrent protection switch and the energy storage unit. This prevents the fan controller from continuing to operate under excessively low voltage conditions that may lead to malfunction or damage, thereby enhancing the stability and reliability of the server system. In addition, by setting different preset voltages and threshold voltages, and integrating the collaborative operation of the mainboard, the overcurrent protection switch, and the energy storage unit, the activation and control over the fan might be achieved to the specific needs of various server systems, thereby enhancing the performance and energy efficiency of the server systems.

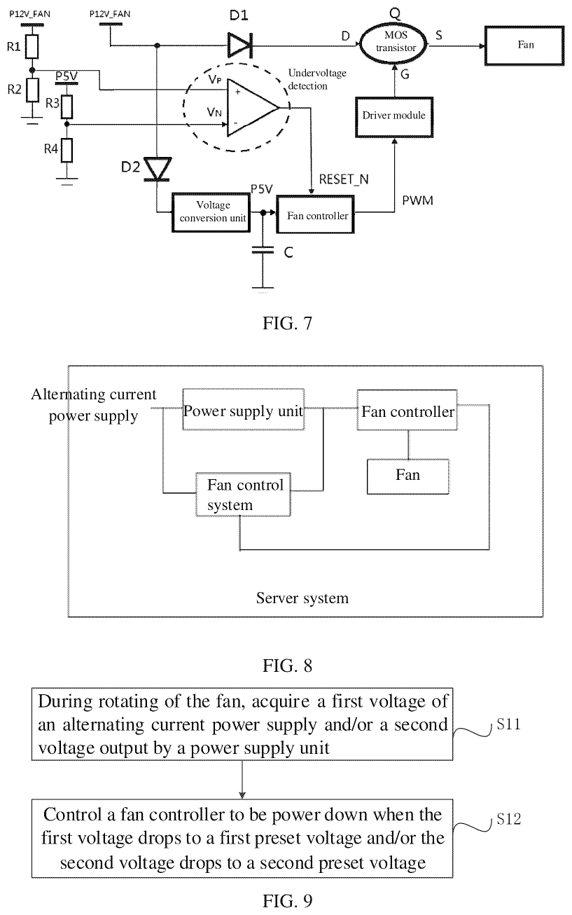

Referring to FIG. 7, FIG. 7 is a schematic diagram illustrating an improved internal power supply for a fan according to the present application.

In some embodiments, the measurement circuit 11 is configured to acquire a second voltage output by the power supply unit during rotating of the fan; the measurement circuit is configured to acquire a second voltage output by the power supply unit during rotating of the fan; the fan control system further includes:

an undervoltage measurement circuit having an input end connected to the output end of the power supply unit and the power terminal of the fan controller and an output end connected to a reset end of the fan controller, configured to compare the second voltage output by the power supply unit with a threshold voltage of the fan controller, and to output a reset signal to the reset end of the fan controller when the second voltage is less than the threshold voltage, thereby resetting the fan controller to trigger the fan controller to re-regulate a rotating speed of the fan.

The undervoltage measurement circuit includes:

a sampling circuit having an input end connected to the power terminal of the fan controller for acquiring the threshold voltage of the fan controller; and

a comparison circuit having a first input end connected to the output end of the measurement circuit 11, a second input end connected to the output end of the sampling circuit, and an output end connected to the reset end of the fan controller, configured to output the reset signal to the reset end of the fan controller when the second voltage output by the power supply unit is less than the threshold voltage of the fan controller, thereby resetting the fan controller to trigger the fan controller to re-regulate the rotating speed of the fan.

In some embodiments, the undervoltage measurement circuit is configured to monitor whether the output voltage of the power supply unit is less than the threshold voltage of the fan controller. The measurement circuit 11 is configured to acquire the output voltage of the power supply unit and connect the power supply unit to the first input end of the comparison circuit. The sampling circuit is configured to detect the threshold voltage of the fan controller and is connected to the second input end of the comparison circuit. The comparison circuit is configured to compare whether the voltage value at the first input end is less than the voltage value at the second input end. In some embodiments, the comparison circuit determines whether the voltage value at the first input end is less than the voltage value at the second input end. If the voltage value at the first input end is lower than the voltage value at the second input end, it indicates that the output voltage of the power supply unit is less than the threshold voltage of the fan controller. Conversely, if the voltage value at the first input end is not less than the voltage value at the second input end, it indicates that the output voltage of the power supply unit is not less than the threshold voltage of the fan controller. In some embodiments, when the measurement circuit 11 is configured to detect the second voltage of the power supply unit, both the measurement circuit 11 and the sampling circuit are resistive voltage divider circuits. The comparison circuit may be implemented as a comparator. When the sampling circuit is a resistive voltage divider circuit, the sampling circuit includes a first resistor (R3 in FIG. 7) and a second resistor (R4 in FIG. 7); the first resistor has one end connected to a power terminal of the fan controller and has the other end connected to one end of the second resistor and served as an output end of the sampling circuit, and the other end of the second resistor is grounded. When the measurement circuit is a resistive voltage divider circuit, the measurement circuit includes a third resistor (R1 in FIG. 7) and a fourth resistor (R2 in FIG. 7); the third resistor has one end connected to an output end of the power supply unit and has the other end connected to one end of the fourth resistor and served as an output end of the measurement circuit, and the other end of the fourth resistor is grounded. When the comparison circuit is a comparator, the comparison circuit is a comparator; a positive input end is connected to the output end of the measurement circuit, a negative input end is connected to the output end of the sampling circuit, and an output end is connected to the reset end of the fan controller, configured to output a low-level signal to the reset end of the fan controller when the second voltage output by the power supply unit is less than the threshold voltage of the fan controller, thereby resetting the fan controller to trigger the fan controller to re-regulate the rotating speed of the fan; the comparison circuit is a comparator; a positive input end is connected to the output end of the measurement circuit, a negative input end is connected to the output end of the sampling circuit, and an output end is connected to the reset end of the fan controller, configured to output a high-level signal to the reset end of the fan controller when the second voltage output by the power supply unit is less than the threshold voltage of the fan controller, thereby resetting the fan controller to trigger the fan controller to re-regulate the rotating speed of the fan.

For example, it is assumed that the second voltage output by the power supply unit in the server system served as a reference voltage for the rotating speed of the fan. When a failure of the alternating current power supply or the power supply unit causes the second voltage to drop below the second preset voltage, the comparison circuit triggers a reset signal and transmits the reset signal to the fan controller. Upon receiving the reset signal, the fan controller will reinitialize, reassess the voltage condition, and adjust the rotating speed of the fan to ensure the thermal dissipation performance of the server system. In FIG. 7, a power supply input end P12V_FAN of the internal circuit of the fan is voltage-divided by resistors R1 and R2 to generate VP connected to a non-inverting input end of the comparator. The P5V output from the voltage conversion unit inside the fan is voltage-divided by resistors R3 and R4 to generate VN connected to an inverting terminal of the comparator. The output signal RESET_N of the voltage comparator is connected to a Reset pin of the fan controller. When the P12V_FAN drops below the undervoltage threshold Vuv, then: VP<VN. The output signal RESET_N of the voltage comparator transitions to a low level. At this time, the fan controller will reset and reinitialize its operation, thereby regulating the rotating speed of the fan according to the standard fan start procedure.

The undervoltage measurement circuit in some embodiments might effectively monitor whether the output voltage of the power supply unit meets the requirements of the fan controller. Through the determination of the comparison circuit, it might be promptly detected whether the output voltage of the power supply unit is less than the threshold voltage, thereby controlling the power down operation of the fan controller. This ensures that, in the event of an insufficient or abnormal power supply, even if the fan controller loses power, timely measures might be implemented to prevent potential damage or malfunction, thereby maintaining the normal operation and stability of the server system.

In some embodiments, the energy storage unit is a capacitor. In some embodiments, the delay circuit 12 is a counter or a timer or an RC circuit.

In some embodiments, the mainboard is configured to stop outputting a closing signal to the delay circuit when the first voltage drops to a first preset voltage and/or the second voltage drops to a second preset voltage, thereby stopping outputting the closing signal to the overcurrent protection switch by delaying the delay circuit for a preset time period, whereby the energy storage unit discharges within the preset time period, whereby the fan controller is power down.

In a second aspect, the present application further provides a server system. Referring to FIG. 8, FIG. 8 is a structural block diagram illustrating a server system according to the present application, the system includes a power supply unit, a mainboard, an overcurrent protection switch, an energy storage unit, a fan controller, a fan, and the fan control system as described in any one of the above.

An input end of the power supply unit is configured to receive an alternating current power supply, an output end of the power supply unit is connected to a power terminal of the mainboard and is connected to the energy storage unit, a power terminal of the fan controller, and a power terminal of the fan via the overcurrent protection switch, an output end of the mainboard is connected to an enabling end of the overcurrent protection switch, and the fan controller is connected to the fan.

In a third aspect, referring to FIG. 9, FIG. 9 is a schematic flowchart of a fan control method according to the present application, the fan control method is applied to the above described fan control system and includes:

S11 During rotating of the fan, acquire a first voltage of an alternating current power supply and/or a second voltage output by a power supply unit; and

In some embodiments, the current voltage status is monitored by acquiring a first voltage of the alternating current power supply and/or a second voltage output by the power supply unit. The first voltage may be directly acquired from an alternating current power supply, and the second voltage may be output from the power supply unit. By monitoring these voltages, the status of the alternating current and the power supply unit might be ascertained in real time, and corresponding control measures might be implemented based on this information. It enables the system to promptly detect voltage drop conditions, thereby providing precise triggering condition for subsequent fan control.

In some embodiments, sensors may be utilized to monitor in real time the voltage of the alternating current power supply and the output voltage of the power supply unit.

S12 When the first voltage drops to a first preset voltage and/or the second voltage drops to a second preset voltage, control the mainboard to continuously output the closing signal to an overcurrent protection switch for a preset time, whereby the energy storage unit discharges for the preset time, thereby controlling the fan controller to be power down.

The design concept of the present embodiment is as follows: by monitoring the voltage of the alternating current power supply and the voltage output by the power supply unit, and setting a preset voltage value, when the voltage drops below the preset voltage, the control mainboard is triggered to continuously output a closing signal for a preset time to the overcurrent protection switch, whereby the energy storage unit discharges for the preset time, thereby controlling the fan controller to be power down to ensure normal operation of the fan.

In some embodiments, the fan controller is configured to control the mainboard to continuously output the closing signal for the preset time to the overcurrent protection switch when an alternating current voltage or an output voltage of a power supply unit drops to a preset voltage level (when the first voltage drops to the first preset voltage and/or the second voltage drops to the second preset voltage), whereby the energy storage unit discharges for the preset time, thereby controlling the fan controller to be power down. Such a fan power down control can realize a power down operation of the fan by controlling an operation state of the fan controller. The operation may be accomplished by turning off the fan controller or by disconnecting the power supply connection between the power supply unit and the fan. By executing this control operation, the system can promptly reduce or halt the operation of the fan, thereby mitigating the risk of insufficient power supply to the fan and preventing the triggering of overcurrent protection.

Further, in some embodiments, the voltage of the alternating current power supply and the voltage output by the power supply unit are monitored during rotating of the fan, and comparing these voltages with a preset voltage. Once the first voltage drops below the first preset voltage or the second voltage drops below the second preset voltage, the mainboard is controlled to continuously output a closing signal to the overcurrent protection switch to prevent the overcurrent protection switch from being disconnected, thereby enabling the energy storage unit to discharge for a preset time to reduce the power supply voltage of the fan controller below the threshold voltage, thereby achieving a power down operation. As such, it is possible to prevent malfunction or damage that may arise from continuing to operate the fan controller under excessively low voltage conditions.

In the implementation process, different preset voltages and threshold voltages might be configured to satisfy the requirements of various server systems. For example, based on the performance and load conditions of the server system, a lower preset voltage and threshold voltage might be configured to power down when the voltage decreases to a certain level, thereby ensuring that the fan controller is not impacted by an excessively low voltage.

In some embodiments, it might be seen that the server system can be ensured to be power down timely when the voltage decreases to a certain level, and a stable power supply can be provided by utilizing the overcurrent protection switch and the energy storage unit. This prevents the fan controller from continuing to operate under excessively low voltage conditions that may lead to malfunction or damage, thereby enhancing the stability and reliability of the server system. In addition, by setting different preset voltages and threshold voltages, and integrating the collaborative operation of the mainboard, the overcurrent protection switch, and the energy storage unit, the activation and control over the fan might be achieved to the needs of various server systems, thereby enhancing the performance and energy efficiency of the server systems.

For example, in the server system, the current supply unit converts a 220V alternating current power supply into a 12V direct current power supply to power the fan controller and the fan, assuming the first preset voltage is set to 200 V and the second preset voltage is set to 8 V. When the voltage of the alternating current power supply drops below 200 V or the voltage output by the power supply unit drops below 8 V, the fan controller will execute a power down operation to ensure the normal operation of the fan.

Further, in some of the embodiments, after acquiring the first voltage of the alternating current power supply and/or the second voltage output by the power supply unit, the method further includes: it is determined whether a first difference between the first reference voltage and the first voltage is greater than a first threshold, and/or it is determined whether a second difference between the second reference voltage and the second voltage is greater than a second threshold; if the first difference is greater than the first threshold, it is determined that the first voltage drops to the first preset voltage; if the second difference is greater than the second threshold, it is determined that the second voltage drops to the second preset voltage.

In some embodiments, in response to determining that the first difference between the first reference voltage and the first voltage is greater than the first threshold, it is determined that the first voltage drops to the first preset voltage. In response to that the first difference between the first reference voltage and the first voltage is greater than the first threshold, it is determined that the second voltage drops to the second preset voltage.

In some embodiments, it is described how to determine whether the voltage drops to a preset voltage based on the difference between the sampled voltage and the corresponding voltage. The voltage monitoring and control process within the system is further clarified, and a method for implementing power down control is provided. Such a power down control method is capable of effectively monitoring the voltage within the server system and implementing timely measures, thereby ensuring the stable operation of the system.

In some embodiments, the fan control system further includes a filtering apparatus provided between the output end of the measurement circuit and the mainboard for filtering the first voltage and/or the second voltage acquired by the measurement circuit, after acquiring the first voltage from the alternating current power supply and/or the second voltage output by the power supply unit, the method further includes: filtering the first voltage and/or the second voltage. Stable power supply voltage information can be acquired. The filtering process can be achieved by utilizing a filter circuit or a filter algorithm. For example, in some embodiments, a capacitive filter may be utilized to filter the acquired first voltage signal and/or second voltage signal, thereby enhancing the stability and reliability of the server system through real-time monitoring and filtering of the power supply voltage.

In some embodiments, the fan control system further includes a prompt apparatus connected to the mainboard for outputting prompt information when it is determined that the first voltage drops to a first preset voltage and/or it is determined that the second voltage drops to a second preset voltage; after it is determined that the first voltage drops to the first preset voltage and/or it is determined that the second voltage drops to the second preset voltage, the method further includes: the prompt apparatus is controlled to output the prompt information. In some embodiments, the prompt apparatus is a voice prompt apparatus and/or a display prompt apparatus and/or a vibrating prompt apparatus.

In some embodiments, the prompt apparatus is configured to provide prompt information to the user after determining that the first voltage drops to the first preset voltage and/or determining that the second voltage drops to the second preset voltage. The prompt apparatus may adopt various forms, such as a voice prompt apparatus, a display prompt apparatus, and/or a vibration prompt apparatus. In some embodiments, when the fan controller detects that the first voltage of the alternating current power supply and/or the second voltage output by the power supply unit is below a preset voltage, the fan controller triggers a power down operation to prevent adverse effects or malfunctions of the fan caused by excessively low voltage. At this time, corresponding prompt information is output to the user via the prompt apparatus, enabling the user to take timely measures to rectify the fault or adjust the power supply. For example, when the first voltage drops to the first preset voltage, the fan controller controls the prompt apparatus to send out a voice prompt, prompting the user of a potential issue with the alternating current power supply. If the second voltage drops to the second preset voltage, the fan controller may display warning information via a display prompt apparatus, or alert the user through a vibration prompt apparatus to attract the user's attention.

In addition, the prompt apparatus may incorporate additional functionalities, such as transmitting messages to the user's mobile phone or email, or uploading fault information to the server's remote monitoring system, enabling technicians to promptly address the fault. Through timely prompts and alarms, the reliability and security of the server system might be enhanced, ensuring the integrity of both the server and the data.

In summary, a more intelligent and reliable fan control method is provided by incorporating a prompt apparatus in conjunction with the fan controller. This method might promptly identify power supply issues and notify the user through various forms of prompt information, thereby enhancing system reliability and user experience.

In some embodiments, when the first voltage drops to the first preset voltage and/or the second voltage drops to the second preset voltage, controlling the mainboard to continuously output the closing signal for the preset time to the overcurrent protection switch, whereby the energy storage unit discharges for the preset time, thereby controlling the fan controller to be power down includes:

it is determined whether a duration for the first voltage dropping to the first preset voltage and/or the second voltage dropping to the second preset voltage reaches a time threshold;

if so, controlling the mainboard to continuously output the closing signal to an overcurrent protection switch for a preset time, whereby the energy storage unit discharges for the preset time, thereby controlling the fan controller to be power down.

In response to that a duration for the first voltage dropping to the first preset voltage and/or the second voltage dropping to the second preset voltage reaches the time threshold, the mainboard is controlled to continuously output a closing signal for a preset time to the overcurrent protection switch, whereby the energy storage unit discharges for the preset time, thereby controlling the fan controller to be power down.

In some embodiments, it is determined whether a duration that the first voltage drops to the first preset voltage and/or the second voltage drops to the second preset voltage reaches a time threshold. This time threshold might be configured based on the requirements of the fan control system. If the duration of the voltage drop is greater than the threshold, it indicates that potential issues may exist and corresponding measures should be implemented. During the operation of the fan, if an abnormality in the power supply is detected, leading to a voltage drop, control measures might be promptly implemented to prevent further damage to the circuit or device. Further, by setting a time threshold, unnecessary power down operations due to transient voltage drops can be avoided, thereby enhancing the system's reliability.

In summary, through the methods described in some embodiments, the issues of insufficient power supply to the fan and triggering of overcurrent protection in a server system might be effectively resolved. This method provides flexibility to adaptively adjust the preset voltage level based on actual conditions and is capable of controlling the operation state of the fan at an appropriate time. As such, the mainboard and other components within the system can function effectively even after the alternating current and the power supply unit resume normal operation, while the risk of overheating and damage to critical components might be mitigated through timely fan control.

In some embodiments, after when the first voltage drops to the first preset voltage and/or the second voltage drops to the second preset voltage, controlling the mainboard to continuously output the closing signal for the preset time to the overcurrent protection switch, whereby the energy storage unit discharges for the preset time, thereby controlling the fan controller to be power down, the method further includes: when the first voltage is recovered and the second voltage is recovered, the fan controller is controlled to be re-power on to restart the fan. In some embodiments, the when the first voltage is recovered and the second voltage is recovered, controlling the fan controller to be re-power on to restart the fan includes: when the first voltage is recovered and the second voltage is recovered, it is delayed to control the fan controller to be re-power on to restart the fan.

In some embodiments, the when the first voltage is recovered and the second voltage is recovered, controlling the fan controller to be re-power on to restart the fan includes: when the first voltage and the second voltage are recovered, it is delayed to control the fan controller to be re-power on. The delay time might be configured as required, ensuring the stability of the power supply, thereby fully ensuring the normal operation of the fan. The delay control might be achieved through a counter or other implementation means.

A core concept of the present embodiment is to determine whether it is necessary to restart the fan by evaluating a condition after the fan controller is power down, and to be re-power on the fan controller by controlling the power supply unit once the voltage is recovered, thereby recovering the operation of the fan. It effectively keeps the safety and stability of the fan and server system, while enabling dynamic control of the fan's operation status based on actual requirements, thereby enhancing the system's energy efficiency and service life.

In terms of technical principle, by monitoring the voltage of the alternating current power supply and the output voltage of the power supply unit, the energy information required for the fan might be acquired in real time. When the voltage drops below a preset threshold, the fan controller is power down to prevent damage to the fan caused by power instability. However, upon voltage recovery, the fan controller is re-power on through a time delay mechanism to ensure the fan is restarted after the power supply stabilizes, thereby preventing frequent starts and stops caused by power fluctuations to extend the service life of the fan. The specific implementation might be accomplished by means of hardware circuits, controllers, and software, for instance, incorporating voltage monitoring into the fan controller and achieving the control and restart of the fan controller through programming.

In some embodiments, the fan control method further includes:

when a preset cooling condition is met, the mainboard is controlled to output the closing signal to the overcurrent protection switch, whereby the overcurrent protection switch is closed after a preset time delay, so as to start the fan.

In some embodiments, the server system further includes an electronic device to be cooled for connection with the mainboard, and the fan control method further includes:

it is determined whether the electronic device to be cooled is connected to the mainboard;

if so, it is determined that the preset cooling condition is met.

In response to that the electronic device to be cooled is connected to the mainboard, it is determined that the preset cooling condition is met.

In some embodiments, the server system further includes an electronic device to be cooled connected to the mainboard. The electronic device to be cooled may be a processor, a graphics card, a memory, or the like. In some embodiments, the electronic device to be cooled may be an OCP network card. Substantial heat may be generated during the server's operation period. To ensure the normal operation of the electronic device to be cooled and extend its service life, it is necessary to dissipate heat timely.

Therefore, in some embodiments, it is determined whether a preset cooling condition is met based on whether the electronic device to be cooled is connected to the mainboard. When the electronic device to be cooled is connected to the mainboard, it indicates a risk of high temperature during system operation, thereby necessitating timely cooling of the electronic device. According to a preset cooling condition, the mainboard might be controlled to output a closing signal to the overcurrent protection switch to close the overcurrent protection switch, thereby starting the fan.

When the fan is started, the speed and rotating speed of the fan might be controlled via the fan controller, thereby facilitating forced air cooling of the electronic device to be cooled and effectively lowering its temperature. In some embodiments, the fan controller might perform closed-loop control of the rotating speed of the fan based on parameters such as the rotating speed and input current, thereby dynamically adjusting the operating state of the fan to achieve optimal heat dissipation efficiency. In addition, the fan controller might also monitor the fault conditions of the fan, such as abnormal rotating speed of the fan, fan stalling, and so on, and issue an alarm or take appropriate measures timely to ensure the stable operation of the system.

In addition, to enhance heat dissipation efficiency, the server system in the above described embodiment is further equipped with an energy storage unit, which is connected to the power terminal of the fan controller. When the fan is power down, the energy storage unit can supply power to the fan, enabling the fan to continue operating for a short period of time and maintaining the heat dissipation efficiency of the system.

In summary, in some embodiments, the present application might achieve intelligent thermal management for the electronic device to be cooled, enhance the stability and heat dissipation efficiency of the server system, and prolong the operation service life of the electronic device.

In some embodiments, the preset time is not less than a preset multiple of the discharge time, where the discharge time is the time required for a power supply voltage of the fan controller to drop to a threshold voltage during the discharge process of the energy storage unit.

In some embodiments, the definition of the preset time may be further clarified based on the above described embodiments. In some embodiments, a preset-time discharge method based on the threshold voltage may be provided. By continuously controlling the mainboard to output a closing signal to the overcurrent protection switch after the power supply voltage of the fan controller drops below a threshold voltage, thereby discharging the energy storage unit for a preset time, and a more intelligent and adaptive fan control is achieved. For example, if the duration for the supply voltage of the fan controller to drop below the threshold voltage during the discharge of the energy storage unit is 2 to 3 seconds, the preset time might be set to 5 seconds. Within this period, the discharge of the energy storage unit ensures that the supply voltage of the fan controller reliably decreases below the threshold voltage, thereby causing the fan controller to be power down.

In some embodiments, the fan control method further includes:

when the first voltage drops to a first preset voltage and/or the second voltage drops to a second preset voltage, the fan controller is reset to trigger the fan controller to re-regulate a rotating speed of the fan.

In some embodiments, the fan controller is controlled to power down when the first voltage of the alternating current power supply drops to a preset first voltage and/or the second voltage output by the power supply unit drops to a preset second voltage. An objective of this operation is to reinitialize the fan controller by powering it off, thereby re-regulating the rotating speed of the fan.

In some embodiments, the change in voltage may be monitored by using a sensor when the first voltage or the second voltage drops to a preset voltage level. The sensor may be connected to the alternating current power supply and the output of the power supply unit to acquire voltage information in real time. Once the first voltage drops to a preset first voltage and/or the second voltage drops to a preset second voltage, the fan controller will be power down by the controller. This might be achieved by disconnecting the power supply connection of the fan controller, for example, by disconnecting the corresponding power switch or disconnecting the power circuit. After being power down, the fan controller may be restarted via a reset or restart mechanism. For example, the fan controller may be triggered to restart by transmitting a reset signal or reapplying a power supply. Once the fan controller is restarted, it will re-regulate the rotating speed of the fan by controlling the power supply and voltage to the fan. An increase of a duty cycle of a PWM signal to 100% during voltage dropping might be prevented to avoid triggering the overcurrent protection switch.

It might be seen that some embodiments of the present application enable automatic control over the power down of the fan controller when the power supply voltage drops to a preset level, and facilitate the re-regulation of the rotating speed of the fan through re-initialization of the fan controller.

In some embodiments, before the mainboard is controlled to continuously output a closing signal to an overcurrent protection switch for a preset time, whereby the energy storage unit discharges for the preset time, thereby controlling the fan controller to be power down, the method further includes:

it is determined whether the voltage output by the power supply unit is less than the threshold voltage of the fan controller;

if less, it is determined that the first voltage drops to the first preset voltage and/or the second voltage drops to the second preset voltage, and proceed to a step of controlling the mainboard to continuously output the closing signal to an overcurrent protection switch for a preset time, whereby the energy storage unit discharges for the preset time, thereby controlling the fan controller to be power down.

In response to the voltage output by the power supply unit being less than a threshold voltage of the fan controller, it is determined that the first voltage drops to the first preset voltage and/or the second voltage drops to the second preset voltage, and proceed to a step of controlling the mainboard to continuously output the closing signal to an overcurrent protection switch for a preset time, whereby the energy storage unit discharges for the preset time, thereby controlling the fan controller to be power down.

In some embodiments, it is determined whether the first voltage or the second voltage has dropped by determining whether the voltage output by the power supply unit is below a threshold voltage of the fan controller. An object of this design is to ensure that, during normal operation of the fan controller, a power down operation is triggered only when the voltage output by the power supply unit drops below a threshold voltage, thereby preventing unnecessary power down. The present embodiment optimizes the energy efficiency and reliability of the server system by determining whether the output voltage of the power supply unit drops below a threshold voltage to trigger power down operation of the fan controller.

In some embodiments, the undervoltage measurement circuit in the fan control system includes a sampling circuit and a comparison circuit for detecting a threshold voltage of the fan controller, where the measurement circuit is connected to a first input end of the comparison circuit, and the sampling circuit is connected to a second input end of the comparison circuit.

It is determined whether the voltage output by the power supply unit is less than the threshold voltage of the fan controller, including

comparing, via the comparison circuit, whether a voltage value at a first input end is less than a voltage value at a second input end of the comparison circuit;

if the voltage value at the first input end is lower than the voltage value at the second input end, it is determined that the second voltage output by the power supply unit is less than the threshold voltage of the fan controller; otherwise, it is determined that the second voltage output by the power supply unit is not below the threshold voltage of the fan controller.

In some embodiments, whether a voltage value at a first input end is less than a voltage value at a second input end of the comparison circuit is compared via the comparison circuit. In response to the voltage value at the first input end being less than the voltage value at the second input end, it is determined that the second voltage output by the power supply unit is less than the threshold voltage of the fan controller; in response to the voltage value at the first input end not being less than the voltage value at the second input end, it is determined that the second voltage output by the power supply unit is not less than the threshold voltage of the fan controller.

In some embodiments, the sampling circuit is configured to monitor whether the output voltage of the power supply unit is below a threshold voltage of the fan controller. The measurement circuit is configured to acquire the output voltage of the power supply unit and connect the power supply unit to the first input end of the comparison circuit. The sampling circuit is configured to detect the threshold voltage of the fan controller and is connected to the second input end of the comparison circuit. The comparison circuit is configured to compare whether the voltage value at the first input end is less than the voltage value at the second input end. In specific implementations, the comparison circuit determines whether the voltage value at the first input end is less than the voltage value at the second input end. If the voltage value at the first input end is lower than the voltage value at the second input end, it indicates that the output voltage of the power supply unit is less than the threshold voltage of the fan controller. Conversely, if the voltage value at the first input end is not less than the voltage value at the second input end, it indicates that the output voltage of the power supply unit is not less than the threshold voltage of the fan controller. In some embodiments, both the measurement circuit and the sampling circuit may be resistive voltage divider circuits. The comparison circuit may be implemented as a comparator.

The undervoltage measurement circuit in some embodiments can effectively monitor whether the output voltage of the power supply unit satisfies the requirements of the fan controller. Through the determination of the comparison circuit, it might be promptly detected whether the output voltage of the power supply unit is less than the threshold voltage, thereby controlling the power down operation of the fan controller. This ensures that, in the event of an insufficient or abnormal power supply, even if the fan controller loses power, timely measures might be implemented to prevent potential damage or malfunction, thereby maintaining the normal operation and stability of the server system.

In some embodiments, the when the first voltage drops to a first preset voltage and/or the second voltage drops to a second preset voltage, resetting the fan controller to trigger the fan controller to re-regulate a rotating speed of the fan includes:

when it is determined that the voltage value at the first input end is less than the voltage value at the second input end, the comparison circuit is triggered to output a reset signal to the fan controller to reset the fan controller, thereby triggering the fan controller to re-regulate the rotating speed of the fan.

In some embodiments, when the first voltage drops to the first preset voltage and/or the second voltage drops to the second preset voltage, the reset signal is output to the fan controller by triggering the comparison circuit, thereby resetting the fan controller to re-regulate the rotating speed of the fan.

In some embodiments, first, when it is determined that the voltage value at the first input end is less than the voltage value at the second input end, the comparison circuit triggers a reset signal. The comparison circuit may be an electronic circuit configured to compare the magnitude relationship between two input values and output a corresponding signal based on the comparison result. The comparison circuit generates a reset signal when the voltage value at the first input end is lower than the voltage value at the second input end. The reset signal can be directly connected to the fan controller to perform a reset operation on the fan controller. The reset operation reinitializes the fan controller, recovering it to its initial state. After resetting, the fan controller is capable of readjusting the rotating speed of the fan according to the current voltage conditions. As such, the functionality of automatically regulating the rotating speed of the fan according to voltage variations can be achieved.

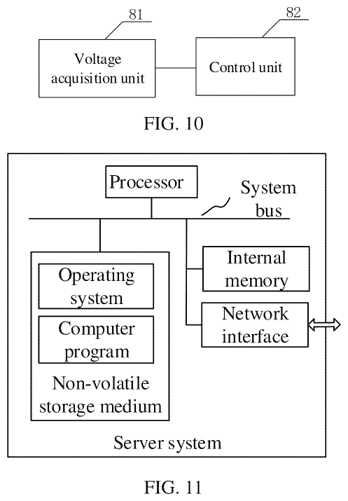

In a fourth aspect, the present application further provides a fan control apparatus. Referring to FIG. 10, FIG. 10 is a structural block diagram illustrating a fan control apparatus according to the present application. The apparatus is applied to the above described fan control system, and the fan control system includes:

a voltage acquisition unit 81 configured to, during rotating of the fan, acquiring a first voltage of an alternating current power supply and/or a second voltage output by a power supply unit; and

a control unit 82 configured to control the fan controller to be power down when the first voltage drops to the first preset voltage and/or the second voltage drops to the second preset voltage.

In some embodiments, the server system further includes a mainboard, an overcurrent protection switch, and an energy storage unit.

The output end of the power supply unit is further connected to the power terminal of the mainboard; the overcurrent protection switch has one end connected to the output end of the power supply unit and the other end connected to the power terminal of the fan controller and the power terminal of the fan; the enabling end of the overcurrent protection switch is connected to the output end of the mainboard; and the energy storage unit is connected to the power terminal of the fan controller.

The control system further includes:

a fan start unit configured to, when meeting a preset cooling condition, control the mainboard to output a closing signal to the overcurrent protection switch, thereby closing the overcurrent protection switch to start the fan.

In some embodiments, the server system further includes an electronic device to be cooled connected to the mainboard, and the method further includes:

an in-situ detection unit configured to determine whether the electronic device to be cooled is connected to the mainboard; if so, it is determined that the preset cooling condition is met.

In some embodiments, the controller is configured to, when the first voltage drops to a first preset voltage and/or the second voltage drops to a second preset voltage, control the mainboard to continuously output the closing signal to the overcurrent protection switch for a preset time, whereby the energy storage unit discharges for the preset time, thereby the fan controller is controlled to be power down.

In some embodiments, the preset time is not less than a preset multiple of the discharge time, where the discharge time is the time required for a power supply voltage of the fan controller to drop to a threshold voltage during the discharge process of the energy storage unit.

In some embodiments, the server system further includes a delay circuit 12, where the delay circuit 12 is provided between the output end of the mainboard and the enabling end of the overcurrent protection switch, where the delay time of the delay circuit 12 is a preset time; and

a controller configured to control the mainboard to stop outputting a closing signal to the time delay circuit 12 when the first voltage drops to the first preset voltage and/or the second voltage drops to the second preset voltage, thereby causing the time delay circuit 12 to stop outputting the closing signal to the overcurrent protection switch after a preset time delay, whereby the energy storage unit discharges for a preset time, thereby controlling the fan controller to be power down.

In some embodiments, the controller is configured to, when the first voltage drops to a first preset voltage and/or the second voltage drops to a second preset voltage, reset the fan controller to trigger the fan controller to re-regulate a rotating speed of the fan.

In some embodiments, the method further includes:

a first determination unit configured to determine whether the voltage output by the power supply unit is less than the threshold voltage of the fan controller before controlling the fan controller to be power down; if less, it is determined that the first voltage drops to the first preset voltage and/or the second voltage drops to the second preset voltage, and proceed to a step of controlling the fan controller to be power down.

In some embodiments, the server system further includes an undervoltage measurement circuit, where the undervoltage monitoring circuit includes a first sampling circuit for sampling a power supply unit, a second sampling circuit for detecting a threshold voltage of a fan controller, and a comparison circuit, the first sampling circuit being connected to a first input end of the comparison circuit, and the second sampling circuit being connected to a second input end of the comparison circuit.

A first determination unit configured to compare, via the comparison circuit, whether a voltage value at a first input end is less than a voltage value at a second input end of the comparison circuit; if the voltage value at the first input end is less than the voltage value at the second input end, determine that a voltage output by a power supply unit is less than a threshold voltage of a fan controller; otherwise, determine that the voltage output by the power supply unit is not less than the threshold voltage of the fan controller.

In some embodiments, the controller is configured to, when it is determined that the voltage value at the first input end is less than the voltage value at the second input end, the comparison circuit is triggered to output a reset signal to the fan controller to reset the fan controller, thereby triggering the fan controller to re-regulate the rotating speed of the fan.

In some embodiments, both the first sampling circuit and the second sampling circuit are resistive voltage divider circuits.

In some embodiments, the method further includes:

a second determination unit configured to determine whether a first difference between the first reference voltage and the first voltage is greater than a first threshold, and/or determine whether a second difference between the second reference voltage and the second voltage is greater than a second threshold; if the first difference is greater than the first threshold, it is determined that the first voltage drops to the first preset voltage; if the second difference is greater than the second threshold, it is determined that the second voltage drops to the second preset voltage.

In some embodiments, the method further includes:

a filtering unit configured to filter the first voltage and/or the second voltage.

In some embodiments, the server system further includes a prompt apparatus, and further includes:

a prompt unit configured to control a prompt apparatus to output prompt information.

In some embodiments, the prompt apparatus is a voice prompt apparatus and/or a display prompt apparatus and/or a vibrating prompt apparatus.

In some embodiments, the controller is configured to determine whether a duration for the first voltage dropping to the first preset voltage and/or the second voltage dropping to the second preset voltage reaches a time threshold; if so, the fan controller is controlled to be power down.

In some embodiments, the method further includes:

a restart unit configured to, when the first voltage is recovered and the second voltage is recovered, control the fan controller to be re-power on to restart the fan.

In some embodiments, the restart unit is configured to, when the first voltage is recovered and the second voltage is recovered, control the fan controller to be re-power on to restart the fan.

For a description of the fan control system, reference is made to the above described embodiments, and details thereof are omitted herein.

In some embodiments, the server system of the present application may further include a memory and one or more processors, where the memory stores computer-readable instructions that, when executed by the one or more processors, cause the one or more processors to perform the steps of the fan control method as provided in any embodiment of the third aspect described above.

In some embodiments, an internal block diagram illustrating the server system may be illustrated as shown in FIG. 11. The computer device includes a processor, a memory, and a network interface connected by a system bus. The processor of the computer device is used for providing computing and control capability. The memory of the computer device includes a non-volatile storage medium and an internal memory. The non-volatile storage medium stores an operating system and a computer program. The internal memory provides an environment for the operation of the operating system and computer programs in the non-volatile storage medium. The network interface of the computer device is used for communicating with an external terminal through a network connection. The computer program, when executed by a processor, implements the fan control method of the present application.

For a description of the fan control apparatus, reference is made to the above described embodiments, and the details will not be reiterated herein.

It should also be noted that the use of relational terms such as first and second, and the like in the description are used solely to distinguish one entity or operation from another entity or operation without necessarily requiring or implying any actual such relationship or order between such entities or operations. Further, the terms “include”, “including”, or any other variation thereof, are intended to cover a non-exclusive inclusion, such that a process, method, article, or device that includes a list of elements does not include only those elements but may include other elements not expressly listed or inherent to such process, method, article, or device. An element proceeded by the phrase “includes a . . . ” does not, without more constraints, preclude the existence of additional identical elements in the process, method, article, or device that includes the element.

The previous description of the disclosed embodiments is provided to enable any person skilled in the art to make or use the present application. Various modifications to these embodiments will be readily apparent to a person skilled in the art, and the generic principles defined herein may be implemented in other embodiments without departing from the spirit or scope of the present application. Thus, the present application is not intended to be limited to the embodiments shown herein but is to be accorded the widest scope consistent with the principles and novel features disclosed herein.

What is claimed is:

1. A fan control system applied to a server system, wherein the server system comprises a power supply unit, a mainboard, an overcurrent protection switch, an energy storage unit, a fan controller, and a fan, an input end of the power supply unit is configured to input an alternating current power supply, an output end of the power supply unit is connected to a power terminal of the mainboard and is connected to the energy storage unit, a power terminal of the fan controller, and a power terminal of the fan via the overcurrent protection switch, an output end of the mainboard is connected to an enabling end of the overcurrent protection switch, and the fan controller is connected to the fan;
wherein the fan control system comprises:
a measurement circuit having an input end connected to at least one of the input end or the output end of the power supply unit and an output end connected to the mainboard, wherein the measurement circuit is configured to acquire at least one of a first voltage of the alternating current power supply or a second voltage output by the power supply unit during rotating of the fan; and
a delay circuit provided between the output end of the mainboard and the enabling end of the overcurrent protection switch, wherein a delay time of the delay circuit is a preset time; and
wherein the mainboard is configured to output a closing signal to the overcurrent protection switch through the delay circuit when the server system meets a preset cooling condition, whereby the overcurrent protection switch is closed after the preset time, and to stop outputting the closing signal to the delay circuit when at least one of the first voltage drops to a first preset voltage or the second voltage drops to a second preset voltage, whereby the energy storage unit discharges within the preset time, thereby the fan controller is powered off.

2. The fan control system according to claim 1, wherein the measurement circuit is configured to acquire the second voltage output by the power supply unit during the rotating of the fan, and the fan control system further comprises:
an undervoltage measurement circuit having an input end connected to the output end of the power supply unit and the power terminal of the fan controller and an output end connected to a reset end of the fan controller, wherein the undervoltage measurement circuit is configured to compare the second voltage output by the power supply unit with a threshold voltage of the fan controller, and to output a reset signal to the reset end of the fan controller when the second voltage is less than the threshold voltage, thereby resetting the fan controller to trigger the fan controller to re-regulate a rotating speed of the fan.

3. The fan control system according to claim 2, wherein the undervoltage measurement circuit comprises:
a sampling circuit having an input end connected to the power terminal of the fan controller for acquiring the threshold voltage of the fan controller; and
a comparison circuit having a first input end connected to the output end of the measurement circuit, a second input end connected to an output end of the sampling circuit, and an output end connected to the reset end of the fan controller, wherein the comparison circuit is configured to output the reset signal to the reset end of the fan controller when the second voltage output by the power supply unit is less than the threshold voltage of the fan controller, thereby resetting the fan controller to trigger the fan controller to re-regulate the rotating speed of the fan.

4. The fan control system according to claim 3, wherein the comparison circuit is a comparator, a positive input end of the comparator is connected to the output end of the measurement circuit, a negative input end of the comparator is connected to the output end of the sampling circuit, an output end of the comparator is connected to the reset end of the fan controller, and the comparator is configured to output a low-level signal to the reset end of the fan controller when the second voltage output by the power supply unit is less than the threshold voltage of the fan controller, thereby resetting the fan controller and triggering the fan controller to re-regulate the rotating speed of the fan;
or, the negative input end of the comparator is connected to the output end of the measurement circuit, the positive input end of the comparator is connected to the output end of the sampling circuit, and the output end of the comparator is connected to the reset end of the fan controller, and the comparator is configured to output a high-level signal to the reset end of the fan controller when the second voltage output by the power supply unit is less than the threshold voltage of the fan controller, thereby resetting the fan controller to trigger the fan controller to re-regulate the rotating speed of the fan.

5. The fan control system according to claim 3, wherein the sampling circuit comprises a first resistor and a second resistor, the first resistor has one end connected to the power terminal of the fan controller and has a second end connected to one end of the second resistor and serving as the output end of the sampling circuit, and a second end of the second resistor is grounded.

6. The fan control system according to claim 1, wherein, when the measurement circuit is configured to detect the second voltage output by the power supply unit, the measurement circuit comprises a third resistor and a fourth resistor, the third resistor has one end connected to the output end of the power supply unit and has a second end connected to one end of the fourth resistor and serving as the output end of the measurement circuit, and a second end of the fourth resistor is grounded.

7. The fan control system according to claim 1, wherein the delay time of the delay circuit is determined according to a type of the fan controller and a type of the fan, the preset time is not less than a preset multiple of a discharge time, and the discharge time is a time required for a power supply voltage of the fan controller to drop to a threshold voltage during a discharge process of the energy storage unit.

8. The fan control system according to claim 1, wherein the energy storage unit is a capacitor.

9. The fan control system according to claim 1, wherein the delay circuit is a timer, a time counter, or a Resistor-Capacitor (RC) circuit.

10. The fan control system according to claim 1, further comprising a filtering apparatus provided between the output end of the measurement circuit and the mainboard for filtering the at least one of the first voltage or the second voltage acquired by the measurement circuit.

11. The fan control system according to claim 1, further comprising a prompt apparatus connected to the mainboard for outputting prompt information at least one of when it is determined that the first voltage drops to the first preset voltage or when it is determined that the second voltage drops to the second preset voltage.

12. The fan control system according to claim 11, wherein the prompt apparatus is at least one of a voice prompt apparatus, a display prompt apparatus, or a vibration prompt apparatus.

13. A server system, comprising a power supply unit, a mainboard, an overcurrent protection switch, an energy storage unit, a fan controller, and a fan, wherein a fan control system is applied to the server system, an input end of the power supply unit is configured to input an alternating current power supply, an output end of the power supply unit is connected to a power terminal of the mainboard and is connected to the energy storage unit, a power terminal of the fan controller, and a power terminal of the fan via the overcurrent protection switch, an output end of the mainboard is connected to an enabling end of the overcurrent protection switch, and the fan controller is connected to the fan;
wherein the fan control system comprises:
a measurement circuit having an input end connected to at least one of the input end or the output end of the power supply unit and an output end connected to the mainboard, wherein the measurement circuit is configured to acquire at least one of a first voltage of the alternating current power supply or a second voltage output by the power supply unit during rotating of the fan; and
a delay circuit provided between the output end of the mainboard and the enabling end of the overcurrent protection switch, wherein a delay time of the delay circuit is a preset time;
wherein the mainboard is configured to output a closing signal to the overcurrent protection switch through the delay circuit when the server system meets a preset cooling condition, whereby the overcurrent protection switch is closed after the preset time, and to stop outputting the closing signal to the delay circuit when at least one of the first voltage drops to a first preset voltage or the second voltage drops to a second preset voltage, whereby the energy storage unit discharges within the preset time, thereby the fan controller is powered off; and
wherein an input end of the fan control system is connected to at least one of the input end or the output end of the power supply unit, and an output end of the fan control system is connected to the fan controller.

14. A fan control method, wherein the fan control method is applied to a fan control system applied to a server system, the server system comprises a power supply unit, a mainboard, an overcurrent protection switch, an energy storage unit, a fan controller, and a fan, an input end of the power supply unit is configured to input an alternating current power supply, an output end of the power supply unit is connected to a power terminal of the mainboard and is connected to the energy storage unit, a power terminal of the fan controller, and a power terminal of the fan via the overcurrent protection switch, an output end of the mainboard is connected to an enabling end of the overcurrent protection switch, and the fan controller is connected to the fan;
the fan control system comprises:
a measurement circuit having an input end connected to at least one of the input end or the output end of the power supply unit and an output end connected to the mainboard, wherein the measurement circuit is configured to acquire at least one of a first voltage of the alternating current power supply or a second voltage output by the power supply unit during rotating of the fan; and
a delay circuit provided between the output end of the mainboard and the enabling end of the overcurrent protection switch, wherein a delay time of the delay circuit is a preset time;
wherein the mainboard is configured to output a closing signal to the overcurrent protection switch through the delay circuit when the server system meets a preset cooling condition, whereby the overcurrent protection switch is closed after the preset time, and to stop outputting the closing signal to the delay circuit when at least one of the first voltage drops to a first preset voltage or the second voltage drops to a second preset voltage, whereby the energy storage unit discharges within the preset time, thereby the fan controller is powered off; and
wherein the method comprises:
during the rotating of the fan, acquiring the at least one of the first voltage of the alternating current power supply or the second voltage output by the power supply unit; and
when at least one of the first voltage drops to the first preset voltage or the second voltage drops to the second preset voltage, controlling the mainboard to continuously output the closing signal to the overcurrent protection switch for the preset time, whereby the energy storage unit discharges for the preset time, thereby controlling the fan controller to be powered down.

15. The fan control method according to claim 14, wherein the when at least one of the first voltage drops to the first preset voltage or the second voltage drops to the second preset voltage, controlling the mainboard to continuously output the closing signal to the overcurrent protection switch for the preset time, whereby the energy storage unit discharges for the preset time, thereby controlling the fan controller to be powered down comprises:
controlling the mainboard to stop outputting the closing signal to the delay circuit when the at least one of the first voltage drops to the first preset voltage or the second voltage drops to the second preset voltage, whereby the delay circuit delays for the preset time and then stops outputting the closing signal to the overcurrent protection switch, whereby the energy storage unit discharges for the preset time, thereby controlling the fan controller to be powered down.

16. The fan control method according to claim 14, after the acquiring the at least one of the first voltage of the alternating current power supply or the second voltage output by the power supply unit, the method further comprises at least one of:
when a first difference is greater than a first threshold, determining that the first voltage drops to the first preset voltage; or
when a second difference is greater than a second threshold, determining that the second voltage drops to the second preset voltage.

17. The fan control method according to claim 14, after the acquiring the at least one of the first voltage of the alternating current power supply or the second voltage output by the power supply unit, the method further comprises:
filtering the at least one of the first voltage or the second voltage.

18. The fan control method according to claim 14, the when at least one of the first voltage drops to the first preset voltage or the second voltage drops to the second preset voltage, controlling the mainboard to continuously output the closing signal to the overcurrent protection switch for the preset time, whereby the energy storage unit discharges for the preset time, thereby controlling the fan controller to be power down comprises:
when a duration for at least one of the first voltage dropping to the first preset voltage or the second voltage dropping to the second preset voltage reaches a time threshold, controlling the mainboard to continuously output the closing signal to the overcurrent protection switch for the preset time, whereby the energy storage unit discharges for the preset time, thereby controlling the fan controller to be powered down.

19. The fan control method according to claim 14, after the when at least one of the first voltage drops to the first preset voltage or the second voltage drops to the second preset voltage, controlling the mainboard to continuously output the closing signal to the overcurrent protection switch for the preset time, whereby the energy storage unit discharges for the preset time, thereby controlling the fan controller to be powered down, the method further comprises:
when the first voltage is recovered and the second voltage is recovered, controlling the fan controller to be re-powered on to restart the fan.

20. The fan control method according to claim 19, the when the first voltage is recovered and the second voltage is recovered, controlling the fan controller to be re-powered on to restart the fan comprises:
when the first voltage is recovered and the second voltage is recovered, delaying to control the fan controller to be re-powered on to restart the fan.
